(19) United States
(12) Patent Application Publication
(10) Pub. No.: US 2025/0176333 A1
(43) Pub. Date: May 29, 2025

(54) LIGHT-EMITTING STRUCTURE AND LIGHT-EMITTING MODULE

(71) Applicant: Lextar Electronics Corporation, Hsinchu City (TW)

(72) Inventors: Wei-Chung CHENG, Hsinchu City (TW); Yun-Yi TIEN, Hsinchu (TW); Hsin-Jung TSAI, Hsinchu City (TW)

(21) Appl. No.: 18/942,007

(22) Filed: Nov. 8, 2024

(30) Foreign Application Priority Data
Nov. 29, 2023 (CN) 202311622134.2
Sep. 27, 2024 (CN) 202411361460.7

(51) Int. Cl. H01L 33/60; H01L 33/50; H01L 33/52

(52) U.S. Cl. CPC H10H 20/856; H10H 20/851; H10H 20/852

(57) ABSTRACT

A light-emitting structure includes a substrate, a light-emitting device, a light reflective layer, and a reflective microstructure. The light-emitting device, which includes a top surface and side surfaces, is disposed on the substrate. The light reflective layer is disposed above the top surface of the light-emitting device to reflect a portion of the light being emitted from the top surface of the light-emitting device towards the side surfaces of the light-emitting device. The reflective microstructure is disposed on the substrate and surrounding the side surfaces of the light-emitting device to reflect the light being emitted from the side surfaces of the light-emitting device.

### CROSS REFERENCE TO RELATED APPLICATIONS

This application claims priority of China Patent Application No. 2023116221342, filed on Nov. 29, 2023, and No. 2024113614607, filed on Sep. 27, 2024, the entirety of which is incorporated by reference herein. disclosure relates to light-emitting structures, and, in particular, to light-emitting structures with reflective microstructures and light-emitting modules having the same.

### Technical Field

The disclosure relates to light-emitting structures, and, in particular, to light-emitting structures with reflective microstructures and light-emitting modules having the same.

### BACKGROUND

### Description of the Related Art

Light-emitting diodes (LEDs) have a small size and high light-emitting directivity. Therefore, for applications that require light uniformity on the light exit surface of the light emitter, LEDs need to be combined with optical designs that meet the requirement of light uniformity.

The LED backlight module of a liquid-crystal display can be used as an example. In the case of multiple LEDs arranged in an array on a light board, as the pitches between LEDs increase, uneven light distribution may occur due to the Lambertian distribution. Therefore, it is necessary to use other optical components to alter the light distribution of LEDs so that even if the spacing between LEDs increase, the emission beam angle emitted from each LED can simultaneously be widened to improve light uniformity. However, as the sizes of LEDs are scaled down, controlling the light distribution of miniature LEDs becomes challenging, making the design of optical components more difficult as well.

### SUMMARY

The present disclosure provides a light-emitting structure and a light-emitting module having the same to solve at least one of the above problems.

An embodiment of the present disclosure provides a light-emitting structure. The light-emitting structure includes a substrate, a light-emitting device, a light reflective layer, and a reflective microstructure. The light-emitting device is disposed on the substrate and includes a top surface and side surfaces. The light reflective layer is disposed above the top surface of the light-emitting device for reflecting a portion of the light emitted from the top surface of the light-emitting device to the side surfaces of the light-emitting device. The reflective microstructure is disposed on the substrate and surrounds the side surfaces of the light-emitting device for reflecting light emitted from the side surfaces of the light-emitting device.

An embodiment of the present disclosure provides a light-emitting module. The light-emitting module includes a plurality of the light-emitting structures mentioned above and arranges them in an array on the substrate.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIG. 1A is a top view of a light-emitting structure, in accordance with various embodiments.

FIG. 1B is a cross-sectional view of a light-emitting structure taken along line A-A′ in FIG. 1A, in accordance with various embodiments.

FIGS. 2A to 2C are cross-sectional views of a light-emitting structure, in accordance with other embodiments, in which the light-emitting structure further includes a package.

FIGS. 3A and 3B are top views of a light-emitting structure, in accordance with other embodiments, in which each of the concentric structures has a different shape.

FIGS. 4A to 4C are top views of a light-emitting structure, in accordance with other embodiments, in which the concentric structures are composed of discrete line segments.

FIGS. 5A and 5B are top views of a light-emitting module, in accordance with various embodiments.

FIG. 6 is a schematic diagram of a light-emitting structure during a light spot size simulation, in accordance with various embodiments.

FIGS. 7A to 7D are diagrams illustrating the simulation results of a light spot size, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including,” “having,” or “comprising,” or the like are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number.

Existing light-emitting devices are directly disposed on the light board, such as on the surface of a printed circuit board (PCB). To alter the light distribution of the light-emitting device, it is necessary to control the light emitted from the five light exit surfaces of the light-emitting device. However, considerations for saving materials and streamlining the manufacturing process make the design challenging. In order to solve the above problems, the present disclosure provides a light reflective layer on the top surface of the light-emitting device to reflect a portion of the light emitted from the top surface of the light-emitting device toward the side surfaces of the light-emitting device. Then, the reflective microstructures around the light-emitting device reflect the light emitted from the side surfaces of the light-emitting device toward the above of the light board to improve light uniformity.

The present disclosure may be applied to light-emitting modules of an illumination or backlight modules of a liquid-crystal display, for example, the direct-type backlight modules using sub-millimeter LEDs (mini LEDs). Generally speaking, when a smaller number of light-emitting diodes (LEDs) are arranged on a light board, the spacing between each LED on the light board becomes larger, leading to issues of uneven light distribution. When the number of LEDs on the light board is increased, the cost is increased. Therefore, by altering the light distribution of the LEDs in accordance with the present disclosure, the emission beam angle of each LED can be widened simultaneously even when the spacing between the LEDs becomes larger due to less LEDs on the light board, thereby improving light uniformity.

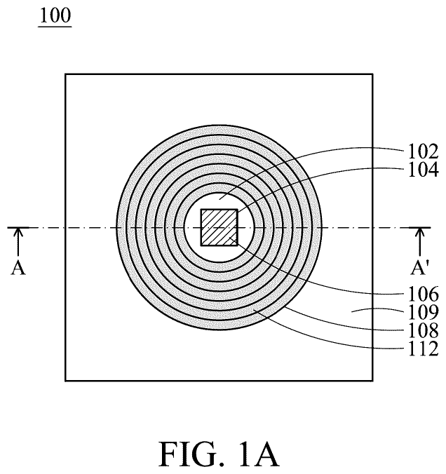

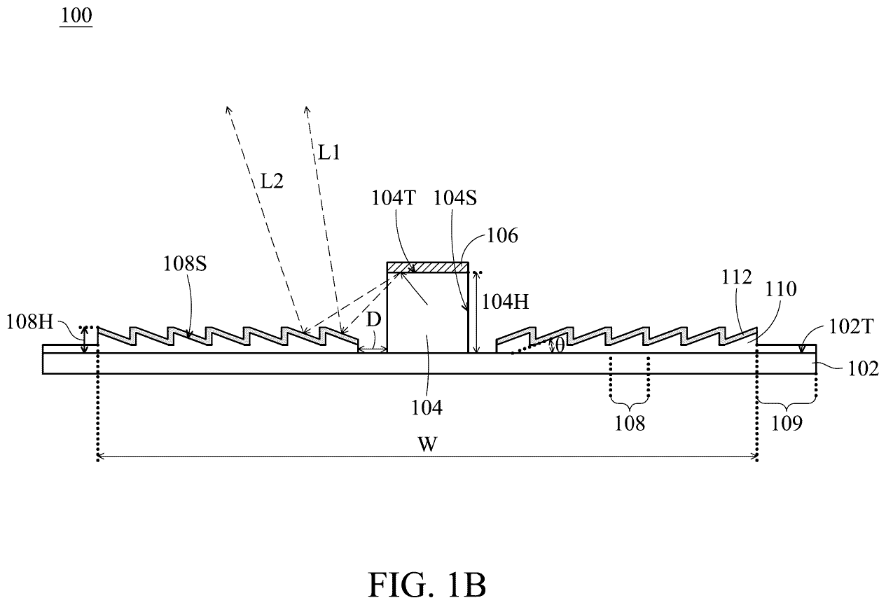

FIGS. 1A and 1B are a top view and a cross-sectional view of a light-emitting structure 100, respectively, in accordance with various embodiments, in which FIG. 1B is taken along line A-A′ in FIG. 1A.

In some embodiments, the light-emitting structure 100 includes a substrate 102, a light-emitting device 104 disposed on the substrate 102, a light reflective layer 106 disposed above the top surface 104T of the light-emitting device 104, and a reflective microstructure 110 disposed on the substrate 102 that surrounds the side surface 104S of the light-emitting device 104. In some embodiments, the substrate 102 may be a substrate with conductive circuits, such as a printed circuit board (PCB). In some embodiments, the substrate can be a rigid substrate, a flexible substrate, a sapphire substrate, a transparent substrate, an opaque substrate, a silicon substrate, a glass substrate, a metal substrate, a ceramic substrate, or a combination thereof, but the disclosure is not limited thereto. The substrate 102 is used to carry electronic components (such as light-emitting devices 104 and driver ICs) located thereon, and the electronic components are electrically connected to the conductive circuits of the substrate.

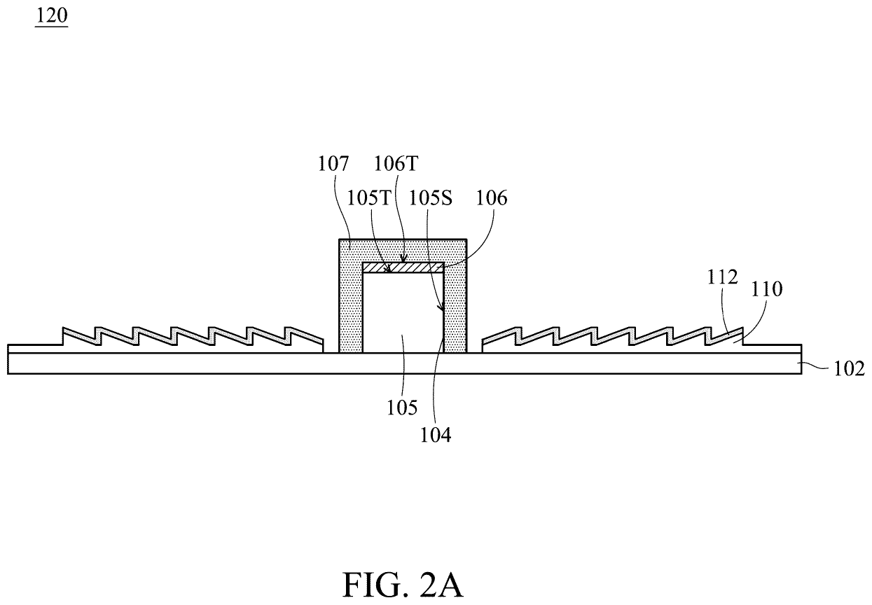

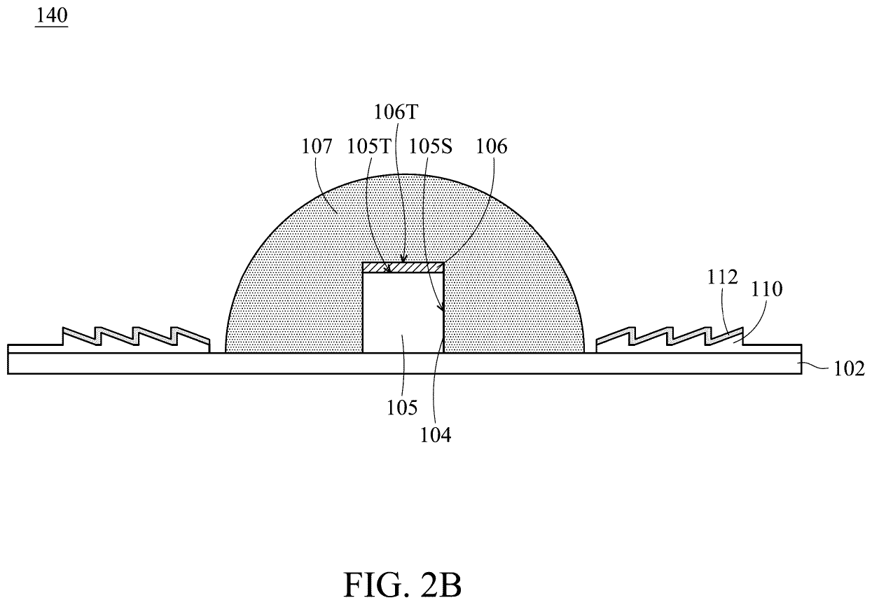

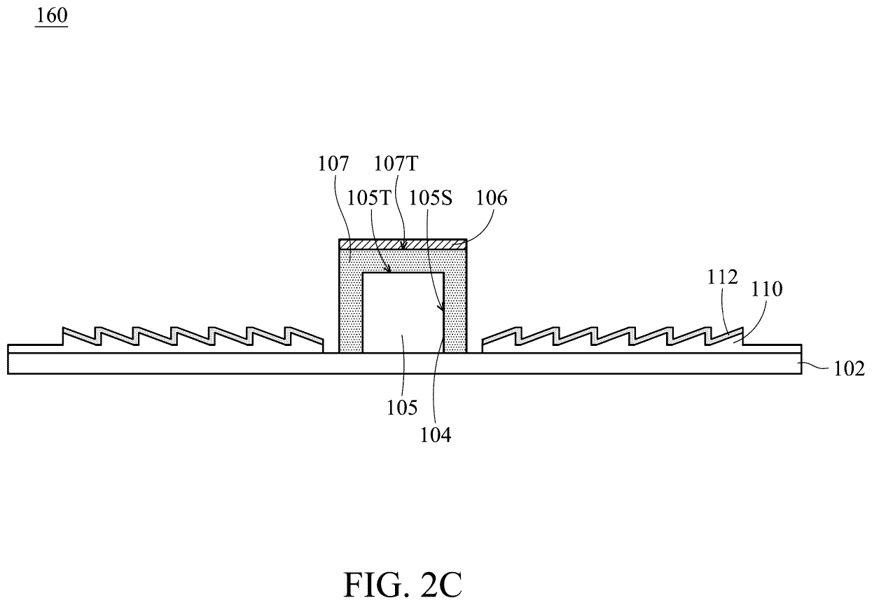

In some embodiments, the light-emitting device 104 is disposed on the substrate 102, and the light-emitting device 104 includes a top surface 104T and side surfaces 104S. In some embodiments, the light-emitting device 104 includes four side surfaces 104S, as shown in FIG. 1A. In addition, the light-emitting device 104 may include a light-emitting diode (LED), such as a sub-millimeter LED (mini LED) or a micro LED, disposed on the substrate 102 in a flip-chip manner. Alternatively, the light-emitting device 104 may be a light-emitting diode package, such as a chip scale package of light-emitting diode (CSP LED), but the disclosure is not limited thereto. In some embodiments, the height 104H of the light-emitting device 104 is 0.4 mm to 2 mm (such as 0.8 mm, 1.0 mm, or 1.1 mm). In some embodiments, the light reflective layer 106 is disposed above the top surface 104T of the light-emitting device 104 to reflect a portion of the light emitted from the top surface 104T of the light-emitting device 104 to the side surfaces 104S of the light-emitting device 104, thereby providing lateral light emission. As shown in FIG. 1B, the light reflective layer 106 is disposed on the top surface 104T of the light-emitting device 104; for example, the light reflective layer 106 is in direct contact with the top surface 104T of the light-emitting device 104, but the disclosure is not limited thereto. In other embodiments, the light reflective layer 106 may not be in direct contact with the top surface 104T of the light-emitting device 104. Further details will be discussed later, in conjunction with FIG. 2C. The light reflective layer 106 can suppress the light emitted from the top surface 104T, preventing the light distribution from being concentrated directly above the light-emitting device 104 to result in uneven light distribution. In some embodiments, the top surface 104T of the light-emitting device 104 does not emit light or substantially does not emit light. In other words, all the light emitted from the top surface 104T of the light-emitting device 104 is substantially reflected by the light reflective layer 106 to the four side surfaces 104S. The light path will be described in detail below.

In some embodiments, the reflectivity of the light reflective layer 106 for the light-emitting wavelength of the light-emitting device 104 is greater than 80%. In some embodiments, the light reflective layer 106 may be a distributed Bragg reflection (DBR) mirror formed of two or more dielectric materials with different refractive indexes stacked alternately. In some embodiments, the DBR mirror includes two or more dielectric materials stacked alternately from zinc selenide (ZnSe), magnesium fluoride (MgF₂), silicon (Si), silicon nitride (SiNₓ), titanium dioxide (TiO₂), tantalum pentoxide (Ta₂O₅), hafnium oxide (HfO₂), silicon dioxide (SiO₂), zirconium dioxide (ZrO₂), and aluminum oxide (Al₂O₃). In some embodiments, the DBR mirror includes two or more materials stacked alternately from aluminum gallium nitride (AlGaN), gallium nitride (GaN), aluminum nitride (AlN), indium gallium nitride (InGaN), aluminum arsenide (AlAs), aluminum gallium arsenide (AlGaAs), gallium phosphide (GaP), aluminum indium phosphide (AlInP), and aluminum indium gallium phosphide (AlInGaP). In some embodiments, the light reflective layer 106 may be a white reflective layer that includes a resin (such as silicone or epoxy resin) and reflective metal oxide particles (such as titanium dioxide, aluminum oxide, silicon oxide, or the like.) dispersed in the resin. In some embodiments, the light reflective layer 106 may be a metal layer (such as a silver layer, an aluminum layer, or the like.).

In some embodiments, the light-emitting device 104 may be a light-emitting diode (LED chip), and the light reflective layer 106 is directly disposed on the top surface of the light-emitting diode, as shown in FIGS. 1A to 1B.

In some embodiments, as shown in FIGS. 2A to 2C, the light-emitting structures 120, 140, and 160 further include a package 107, and the light-emitting device 104 includes a light-emitting diode 105. Therefore, the light-emitting device 104 and the package 107 may constitute a package of light-emitting diode. As shown in FIGS. 2A and 2B, the light reflective layer 106 is disposed on the top surface of the light-emitting diode 105, and the package 107 encapsulates both the light-emitting diode 105 and the light reflective layer 106. Specifically, the package 107 covers the top surface 106T of the light reflective layer 106 and four sides 105S of the light-emitting diode 105. In addition, the package 107 may have a profile that is similar to or same as that of the light-emitting device 104 (FIG. 2A) or may have a semicircular cross-sectional profile (FIG. 2B), but the disclosure is not limited thereto. In other embodiments, the package 107 may have cross-sectional profiles with different shapes. In some embodiments, the package 107 may encapsulate the light-emitting diode 105, and the light reflective layer 106 is disposed on the top surface 107T of the package 107, as shown in FIG. 2C. In other words, the light reflective layer 106 is in direct contact with the top surface 107T of the package 107, but not in direct contact with the top surface 105T of the light-emitting diode 105.

In some embodiments, the package 107 may be a light transmitting material, such as epoxy, silicone, or glass, and the like. In some embodiments, the package 107 may further include wavelength converting materials, such as quantum dot materials, phosphors, others suitable materials, or a combination thereof. The light-emitting structures 120, 140, and 160 may function as backlighting for a display. In some embodiments where the light-emitting structures 120, 140, and 160 emit white light, the light-emitting device 104 may be a blue light-emitting diode that emits blue light. The package 107 includes yellow phosphor, which absorbs portions of the blue light and converts it into yellow light. The yellow light combines with the remaining blue light to produce white light. Alternatively, the package 107 includes red and green wavelength converting materials that absorb portions of the blue light and convert it into red and green light, respectively. The red light and green light combine with the remaining blue light to produce white light. The red wavelength converting material may be red phosphor or red quantum dots, while the green wavelength converting material maybe green phosphor or green quantum dots.

In some embodiments, the package 107 may be formed on the substrate 102 using compression molding, injection molding, or dot dispensing, and the like, and encapsulate the light-emitting device 104 and/or the light reflective layer 106.

Referring back to FIGS. 1A and 1B, in some embodiments, the reflective microstructure 110 is disposed on the substrate 102 and surrounds the light-emitting device 104 to reflect light emitted from the side surfaces 104S of the light-emitting device upward. In some embodiments, the reflective microstructure 110 is made of polyethylene terephthalate (PET), ultraviolet (UV) curing glue, poly(methyl methacrylate) (PMMA), polycarbonate (PC), silicone, or a combination thereof. In some embodiments, the reflective microstructure 110 may be formed by using compression molding, or the like.

In some embodiments, the reflective microstructure 110 has a jagged shape in the cross-sectional view, as shown in FIG. 1B. In some embodiments, the reflective microstructure 110 includes a plurality of concentric structures 108, each having an inclined surface 108S facing the light-emitting device 104. Although FIGS. 1A and 1B only show seven concentric structures 108, the present disclosure is not limited thereto, and any number of the concentric structures 108 can be arranged according to actual requirements. In some embodiments, the reflective microstructure 110 also includes a flat portion 109 around the concentric structures 108.

Specifically, a portion of the light emitted from the top surface 104T of the light-emitting device 104 is reflected (or fully reflected) by the light reflection layer 106 disposed on the top surface 104T of the light-emitting device 104 towards the four side surfaces 104S to provide lateral emission. After the light emitted from the side surfaces 104S reaches the reflective microstructure 110, it is reflected toward above the substrate 102 through the inclined surface 108S of the concentric structures 108 (as shown in the light paths L1 and L2) to obtain a broader light distribution and improve light uniformity.

In some embodiments, the angle θ between the inclined surface 108S of the concentric structure 108 and the upper surface 102T of the substrate 102 is 10 degrees to 30 degrees (such as 15 degrees to 25 degrees), which depends on the height 104H of the light-emitting device 104. If the angle θ is less than 10 degrees or greater than 30 degrees, the light emitted from the side surfaces 104S of the light-emitting device 104 cannot be effectively reflected toward above the substrate 102. In some embodiments, each of the inclined surfaces 108S of the concentric structure 108 has the same angle θ with the substrate 102, as shown in FIG. 1B, but the disclosure is not limited thereto. The angle θ may gradually become larger or smaller from the inner ring to the outer ring, with the angle θ being controlled between 10 degrees and 30 degrees. In one embodiment, each inclined surface 108S of the concentric structures 108 may have a different angle θ with the substrate 102. The term “different” used herein means that each inclined surface 108S has various angles θ with the substrate 102, rather than gradually becoming larger or smaller from the inner ring to the outer ring. Therefore, the light distribution (or light spot) can be controlled by adjusting the angle θ of each inclined surface 108S with the substrate 102, thereby achieving excellent light uniformity.

In some embodiments, the pitch between each inclined surface 108S is 0.1 mm to 1 mm (such as 0.2 mm or 0.4 mm). When the pitch is less than 0.1 mm, the manufacture of concentric structures 108 is difficult even though light uniformity maybe achieved better. When the pitch is greater than 1 mm, the control ability of the light is poor due to the small number of inclined surfaces 108S of the concentric structures 108.

In some embodiments, the outer diameter W of the outermost concentric structure 108 of the reflective microstructure 110 is 8 mm to 16 mm (such as 10 mm or 13.4 mm). In some embodiments, the innermost concentric structure 108 is separated from the light-emitting device 104 by a distance D (such as 0.6 mm or 1 mm). The term “distance D” used herein refers to the shortest distance between the light-emitting device 104 and the concentric structure 108. In other words, in the top view, the concentric structure 108 and the light-emitting device 104 are separated by the substrate 102, but the greater the distance D, the worse the uniformity of the reflected light.

In some embodiments, the height 108H of the concentric structures 108 is 0.05 mm to 0.5 mm (such as 0.2 mm or 0.25 mm), and the height 108H is equal to the distance between the topmost of the concentric structures 108 and the substrate 102. When a certain angle θ range is fixed, if the height 108H is less than 0.05 mm, a larger number of concentric structures 108 are required under the same area of the substrate 102. It requires higher precision of mold microstructure fabrication and control of transfer shrinkage. On the contrary, when the height 108H is greater than 0.5 mm, there are two drawbacks. First, when the height 104H is 1 mm to 1.5 mm, the inner concentric structure 108 reflects most of the light, thereby blocking the reflected light from reaching the outer concentric structure 108. Second, a height 108H greater than 0.5 mm also implies a reduction in the number of concentric structures 108, making it insufficient to effectively control the quantity of concentric structures 108 for adjusting the light distribution. In one embodiment, each concentric structure 108 has the same height 108H.

In some embodiments, the ratio of the maximum height 108H of the concentric structures 108 to the height 104H of the light-emitting device 104 is less than ⅓ (such as 0.18 or 0.25), or in the range of 1/10 to ⅕, to make the emission beam angle of the light-emitting device 104 broader. If the ratio is greater than ⅓, the height 108H of the inner concentric structures 108 becomes too high, thus blocking the light path from the emission of light from the side surface 104S of the light-emitting device 104 to the outer concentric structures 108. This, in turn, reduces the effectiveness of the reflection towards the substrate 102 above.

In some embodiments, the reflective microstructure 110 further includes a reflective layer 112 disposed on the surface of the concentric structures 108 (that is, not disposed on the flat portion 109). In some embodiments, the reflectivity of the reflective layer 112 for the light wavelength of the light-emitting device 104 is greater than 96% (such as 97%, 98%, or 99%) to effectively reflect the light emitted from the four side surfaces 104S of the light-emitting device 104 toward above the substrate 102. In some embodiments, the reflective layer 112 may be metal (such as silver or aluminum), which may be formed on the concentric structures 108 by electroplating or other methods. In some embodiments, the reflective layer 112 may be a polymer material doped with reflective particles, which may be formed on the concentric structure 108 by coating or other methods. The reflective particles may include titanium oxide, aluminum oxide, zirconium oxide, silicon oxide, or other suitable metal oxides. The polymers may include silicone, epoxy resin, acrylic glue, or a combination thereof. In some embodiments, the reflective layer 112 may be a reflective layer doped with hollow particle structures.

Specifically, the present disclosure uses the light reflection layer 106 disposed on the top surface 104T of the light-emitting device 104 to partially reflect (or fully reflect) the light emitted from the top surface 104T of the light-emitting device 104 to the side surface 104S. Then, the light emitted from the side 104S of the light-emitting device is reflected toward above the substrate 102 by the reflective microstructure 110 disposed on the substrate 102 and surrounding the light-emitting device 104. By adjusting the angle θ between the inclined surfaces 108S of the concentric structures 108 and the top surface 102T of the substrate 102, the light distribution of the light-emitting devices 104 can become broader. This allows for maintaining a certain level of light uniformity even when the spacing between the light-emitting devices 104 increases.

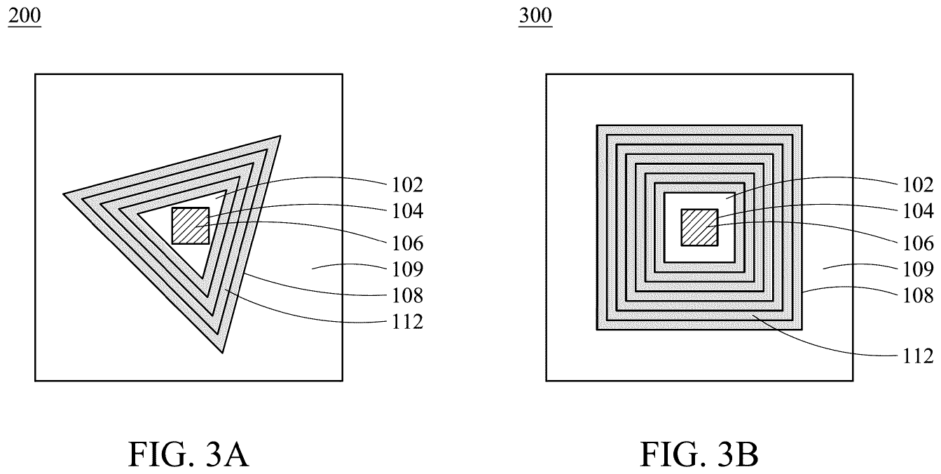

FIGS. 3A and 3B are top views of a light-emitting structure 200 and 300, in accordance with other embodiments. In some embodiments, the concentric structures 108 are concentric circles (as shown in FIG. 1A), concentric triangles (as shown in FIG. 3A), concentric squares (as shown in FIG. 3B), or concentric polygons, but the disclosure is not limited thereto. Except for the shape of the concentric structures 108, the remaining configurations are as described above and will not be repeated herein for brevity.

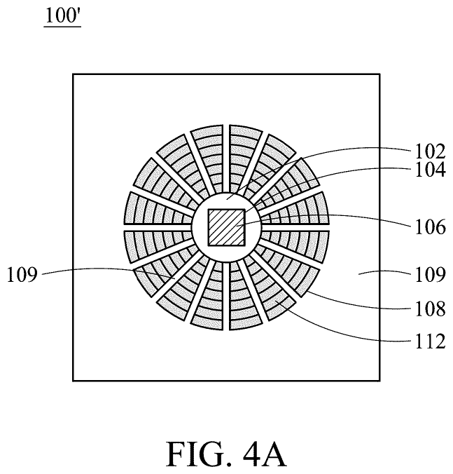

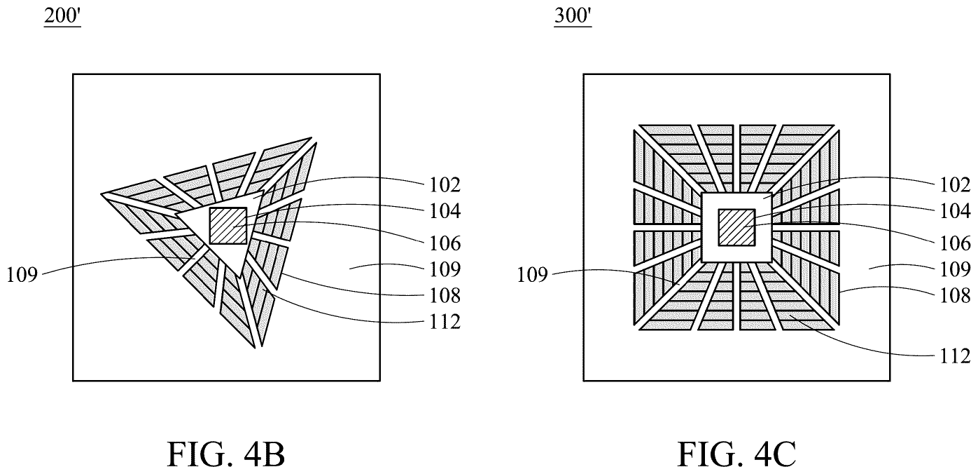

FIGS. 4A to 4C are top views of a light-emitting structure 100′, 200′, and 300′, in accordance with other embodiments. In the embodiment of FIGS. 4A to 4C, the concentric structures 108 are composed of discrete line segments in the top view, and adjacent line segments of the concentric structures 108 are separated by the flat portion 109. The light-emitting structure 100′ in FIG. 4A is similar to the light-emitting structure 100 in FIG. 1A; the light-emitting structure 200′ in FIG. 4B is similar to the light-emitting structure 200 in FIG. 3A; and the light-emitting structure 300′ in FIG. 4C is similar to the light-emitting structure 300 in FIG. 3B. Except that the concentric structures 108 are composed of discrete line segments, the other configurations are as described above and will not be repeated herein for brevity.

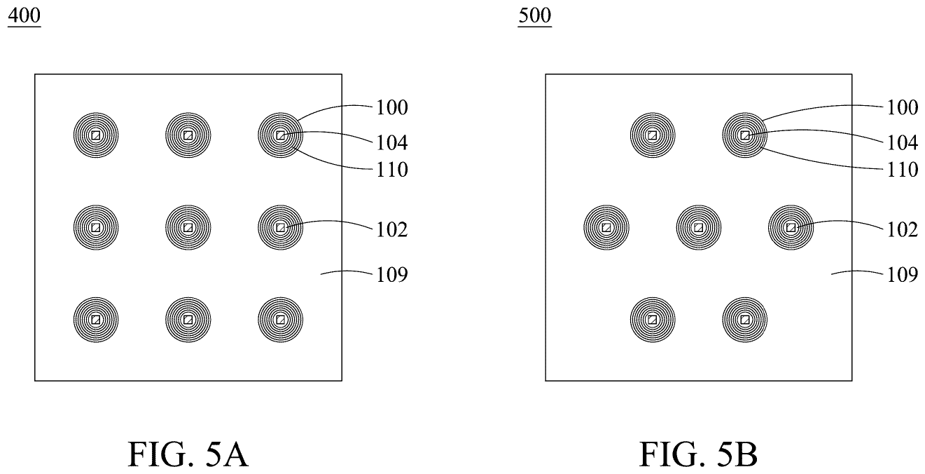

FIGS. 5A and 5B are top views of a light-emitting module 400 and 500, in accordance with various embodiments.

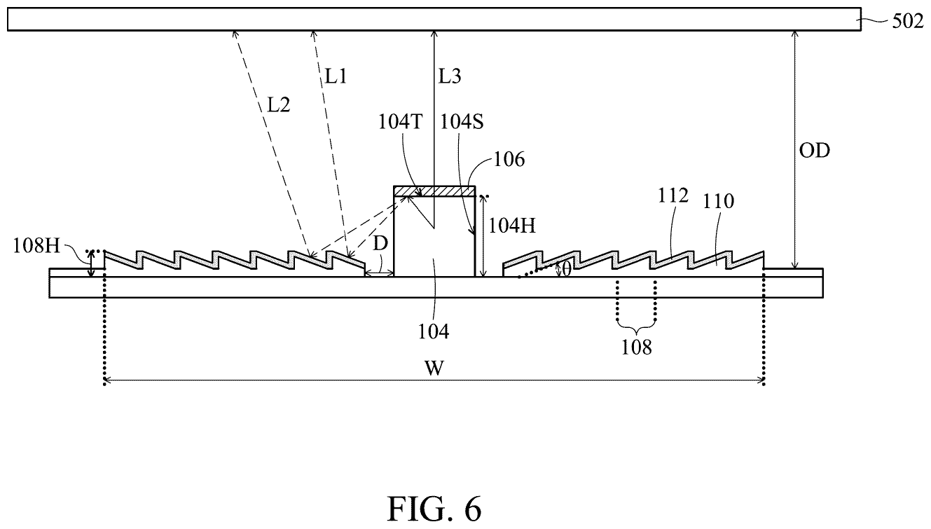

In some embodiments, the light-emitting module 400 or 500 includes a plurality of the above-described light-emitting structures 100 arranged in an array on the substrate 102. When the light-emitting devices 104 of the light-emitting module 400 or 500 are periodically arranged in an array, an increase in the distance between the arranged light-emitting devices 104 can result in uneven light emission on the light source or backlighting output surface (e.g., the emission surface 502 in FIG. 6). To address the above issue, that is, to widen the emission beam angle of the light-emitting devices 104 when the spacing between each light-emitting device 104 increases, the present disclosure provides the light-emitting structure 100 with the light reflection layer 106 disposed on the top surface of the light-emitting devices 104 and the reflective microstructures 110 around the light-emitting device 104 to improve light uniformity.

The light-emitting module 400 in FIG. 5A shows a rectangular array composed of nine light-emitting structures 100, and FIG. 5B shows a hexagonal array composed of seven light-emitting structures 100. It should be noted that the number of light-emitting structures 100 and the arrangement of the arrays are not limited thereto, and any suitable arrangement can be used according to requirements.

In some embodiments, a plurality of light-emitting devices 104 are first formed on the substrate 102, and then a plurality of reflective microstructures 110 are disposed on the substrate 102 to form the light-emitting module 400 or 500. The plurality of reflective microstructures 110 are a continuous structure connected to each other by flat portions 109.

In addition, the light-emitting structures of the light-emitting modules 400 and 500 are not limited to the light-emitting structure 100 in FIG. 1A and may be any one of the light-emitting structures 200 and 300 in FIG. 3A to 3B, the light-emitting structures 100′, 200′, and 300′ in FIG. 4A to 4C, or a combination thereof.

FIG. 6 is a schematic diagram of a light-emitting structure 100 during a light spot size simulation, in accordance with various embodiments. In the absence of a light reflective layer 106 on the top surface 104T of the light-emitting device 104, the light can be emitted from both of the side surfaces 104S of the light-emitting device 104 (as shown in the light paths L1 and L2) or from the top surface 104T (as shown in the light path L3) to reach the light exit surface 502. When a light reflective layer 106 is present, most (or all) of the light is emitted from the side surfaces 104S of the light-emitting device 104 (as shown in the light paths L1 and L2) and reflected by a plurality of reflective microstructures 110 on the substrate 102 to reach the light exit surface 502. In some embodiments, the light exit surface 502 may be, for example, an optical film of a backlight module, such as a diffusion plate or diffusion film composed of scattering particles.

During the simulation process, the optical distance (OD) between the light-emitting device 104 and the light exit surface 502 was fixed at 12 mm, and the dimensions of the light-emitting device 104, the concentric structures 108, and the light reflective layer 106 are shown in Table 1.

TABLE 1

| | | | | | | Shortest | |
|---|---|---|---|---|---|---|---|
| | | | | | | distance | |
| | | | | | | between | |
| | Light- | | | | | the light- | |
| | emitting | | | | | emitting | Light |
| | device | | Concentric structures | | | device to the | reflective |
| | | | Outer | | | concentric | layer |
| | Width | Height | diameter | Height | | structures | Thickness |
| | (mm) | (mm) | (mm) | (mm) | Angle | (mm) | (mm) |
| Comparative | 1.2 | 1.1 | 10 | 0.2 | 10°~35° | 1 | — |
| Example | | | | | | | |
| Example 1 | 1.2 | 0.8 | 10 | 0.2 | 12°~40° | 1 | 0.1 |
| Example 2 | 1.2 | 1.1 | 10 | 0.2 | 10°~35° | 1 | 0.1 |
| Example 3 | 1.2 | 1.0 | 13.4 | 0.25 | 8°~40° | 0.6 | 0.1 |

The Comparative Example involves the absence of the light reflective layer 106, while in Examples 1, 2, and 3, a light reflective layer 106 with a thickness of 0.1 mm is disposed on the top surface 104T of the light-emitting device 104. According to the height 104H of the light-emitting device 104, the outer diameter W, the height 108H, the angle θ of the concentric structure 108, and the distance D between the light-emitting device 104 and the concentric structure 108 were adjusted to simulate the spot size.

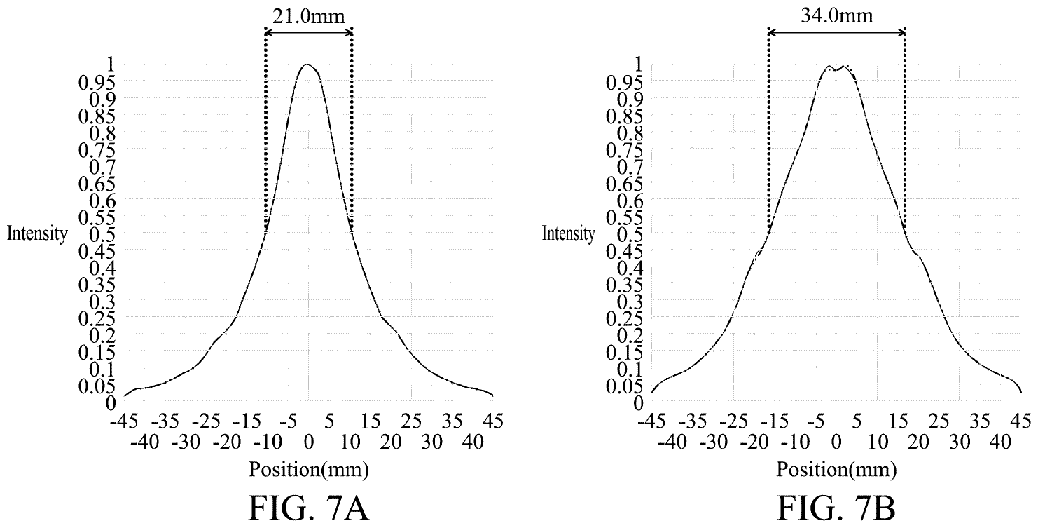

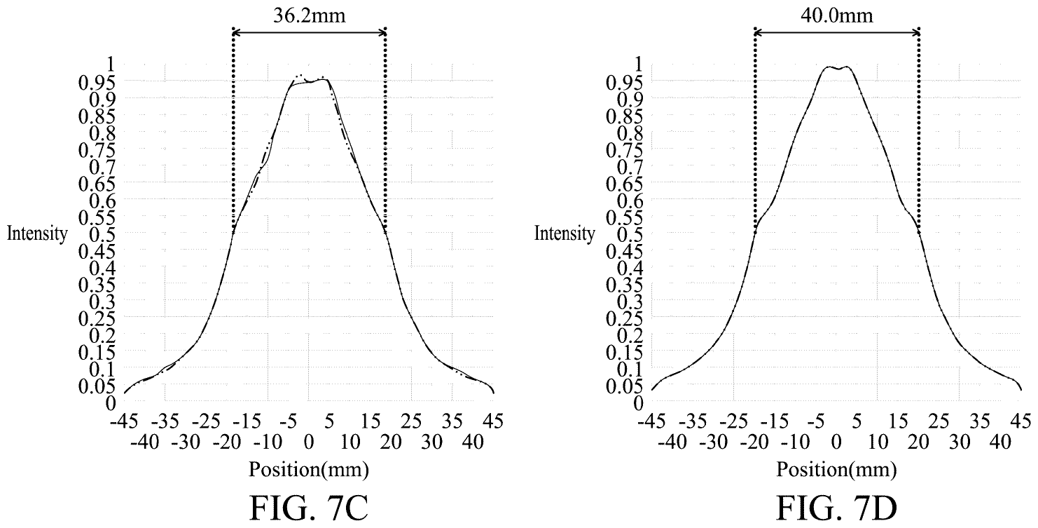

In some embodiments, optical analysis software TracePro and LightTools were used to simulate the light spot size of the light-emitting structure 100. The simulation results are shown in FIGS. 7A to 7D and Table 2.

TABLE 2

| | Comparative | Example | Example | Example |
|---|---|---|---|---|
| Spot size | Example | 1 | 2 | 3 |
| Strength diameter | 21.0 | 34.0 | 36.2 | 40.0 |
| at 50% intensity | | | | |
| (mm) | | | | |

FIGS. 7A to 7D are diagrams illustrating the simulation results of a light spot size, in accordance with various embodiments, in which the X-axis is position (mm) and the Y-axis is intensity (arbitrary units). FIG. 7A shows the simulation result of the Comparative Example, and FIGS. 7B to 7D show the simulation results of Example 1, 2, and 3, respectively. According to the simulation results, compared with Example 1 (34.0 mm), Example 2 (36.2 mm), and Example 3 (40.0 mm), the light spot size of the Comparative Example is the smallest (21.0 mm) value at 50% intensity. In other words, with the presence of the light reflective layer 106 on the top surface 104T of the light-emitting device 104, the light-emitting structure 100 has a wider emission beam angle. In addition, in the scenario where the light reflection layer 106 is present on the top surface 104T of the light-emitting device 104 (to reflect at least a portion of the light emitted from the top surface 104T to the side surfaces 104S), the outer diameter W, the height 108H, the angle θ of the concentric structure 108, and the distance D between the light-emitting device 104 and the concentric structure 108 can be adjusted according to the height 104H of the light-emitting device 104 to widen the emission beam angle and improve light uniformity.

The light-emitting structure and the light-emitting module having the same in the present disclosure provide various advantages. For example, in the present disclosure, the light reflective layer disposed on the top surface of the light-emitting device can effectively control the light on the five light exit surfaces of the light-emitting device. The reflective microstructure disposed on the substrate around the light-emitting device can widen the emission beam angle of the light-emitting device. This not only ensures good light uniformity when the spacing between each light-emitting device increases, but also reduces the number of light-emitting devices, thereby reducing costs.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting structure, comprising:
a substrate;
a light-emitting device disposed on the substrate, and the light-emitting device comprising a top surface and side surfaces;
a light reflective layer disposed above the top surface of the light-emitting device for reflecting a portion of light emitted from the top surface of the light-emitting device to the side surfaces of the light-emitting device; and
a reflective microstructure disposed on the substrate and surrounding the side surfaces of the light-emitting device for reflecting light emitted from the side surfaces of the light-emitting device.

2. The light-emitting structure of claim 1, wherein the reflective microstructure has a jagged shape in a cross-sectional view.

3. The light-emitting structure of claim 1, wherein the reflective microstructure further comprises:
a plurality of concentric structures, each having an inclined surface facing the light-emitting device; and
a reflective layer disposed on the inclined surfaces of the concentric structures.

4. The light-emitting structure of claim 3, wherein a reflectivity of the reflective layer for a light-emitting wavelength of the light-emitting device is greater than 96%.

5. The light-emitting structure of claim 4, wherein the reflective layer comprises metal, or a polymer material doped with reflective particles.

6. The light-emitting structure of claim 3, wherein an angle between the inclined surface of the concentric structures and an upper surface of the substrate is 10 degrees to 30 degrees.

7. The light-emitting structure of claim 6, wherein each of the inclined surfaces of the concentric structures has a different angle with the substrate.

8. The light-emitting structure of claim 3, wherein a ratio of a maximum height of the concentric structures to a height of the light-emitting device is less than ⅓.

9. The light-emitting structure of claim 3, wherein the concentric structures are concentric circles, concentric triangles, concentric squares, or concentric polygons in a top view.

10. The light-emitting structure of claim 3, wherein each of the concentric structures has a same height.

11. The light-emitting structure of claim 3, wherein a pitch between adjacent ones of the inclined surface of the concentric structures is 0.1 mm to 1 mm.

12. The light-emitting structure of claim 3, wherein the concentric structures are composed of discrete line segments in the top view.

13. The light-emitting structure of claim 1, wherein the reflective microstructure is made of PET, UV resin, PMMA, PC, silicone, or a combination thereof.

14. The light-emitting structure of claim 1, wherein the light reflective layer comprises a distributed Bragg reflection (DBR) mirror, metal or a resin mixed reflective metal oxide particles.

15. The light-emitting structure of claim 1, wherein the light-emitting device comprises a light-emitting diode, and the light reflective layer is disposed on a top surface of the light-emitting diode.

16. The light-emitting structure of claim 15, further comprising a package encapsulating the light-emitting diode and the light reflective layer.

17. The light-emitting structure of claim 1, wherein the light-emitting device comprises a light-emitting diode, and the light-emitting structure further comprises a package encapsulating the light-emitting diode, and the light reflective layer is disposed on a top surface of the package.

18. The light-emitting structure of claim 16, wherein the package comprises a wavelength converting material.

19. A light-emitting module, comprising:
a plurality of the light-emitting structures of claim 1 arranged in an array on the substrate.

20. The light-emitting module of claim 19, wherein the array is a hexagonal array.
